(19) United States
(12) Patent Application Publication
(10) Pub. No.: US 2006/0065386 A1
(43) Pub. Date: Mar. 30, 2006

(54) Self-actuating and regulating heat exchange system

(76) Inventor: Mohammed Alam, Milpitas, CA (US)

Correspondence Address: Mohammed Alam, APT # 222, 231 Dixon Landing Road, Milpitas, CA, 95035, US

(21) Appl. No.: 11/194,420

(22) Filed: Aug. 1, 2005

Related U.S. Application Data
(60) Provisional application No. 60/606,056, filed on Aug. 31, 2004.

(51) Int. Cl. H05K 7/20

(52) U.S. Cl. 165/104.33; 361/700

(57) ABSTRACT

A self-actuating and self regulation heat exchange system comprising: evaporator 16, condenser 34, bladder sub-system 42, phase-change fluid 24 and connecting tubes, is a device and an apparatus useful to transport thermal energy from a relatively hot zone to a relatively cold zone, over distance, and around or through obstructions. The bladder sub system, consisting of an expandable bladder and two one-way check-valves, utilizes the pressure difference in the system created during evaporation and condensation to make the phase-change fluid circulate inside the closed loop system, transferring thermal energy from evaporator to condenser. The operation of the device is self started, self regulated and the device is almost independent of gravity, and the orientation.

This application claims the benefit of provisional patent application 60/606,056, filed 31 Aug. 2004 to USPTO by the same inventor.

### TECHNICAL FIELD

This present invention relates generally to mechanisms which transport thermal energy and more particularly, cooling systems used with electronic, electrical, mechanical, chemical or other heat producing components.

### BACKGROUND ART

Many operating devices need cooling to operate smoothly and efficiently. Some of these devices and components, such as electronic circuit board components and semiconductor chips, present special problems due to their relatively small size, rapid heat buildup and compact installation parameters. Various devices, generally referred to as heat sinks, are utilized in order to keep the components within prescribed temperature ranges so they are able to operate continuously and efficiently without damage to the elements and circuitry.

The increasing importance of thermal transport technology is generally dictated by the broadening of the areas of its application in areas including: cooling semiconductor devices, manufacturing processes, heat recovery, electrical and electronics cooling, air conditioning, solar energy collection, motor and engine cooling, and thermal management in outer-space structures. All application mentioned looks for a common requirement, which is to facilitate and control the transportation of thermal energy.

For any two regions which exhibit a significant and measurable difference in temperature, a hot zone, which may be termed as a heat-source and a cold zone, termed a heat-sink, production of thermal energy in any way including passing electricity, burning fuels, mechanical friction or others can raise temperature of the heat-source unless extra heat is removed in some way. There are requirements to move thermal energy over separating distances and around obstructions, from the source to the sink, to keep the heat-source temperature within workable range. In addition to forced air, forced liquid cooling system, some phase-change thermal transport devices have been developed in order to satisfy these requirements.

For a phase-change heat transfer system, the evaporation of a liquid, transport of the vapor through a duct to the heat-sink, condensation and subsequent liquid return to the evaporator is a well known method for transporting thermal energy. This action is efficient for higher rate of thermal energy transfer and consistently employed in all such devices under consideration. The most important requirement for the device to cycle continuously is: the condensate must return to the evaporator.

Up until now, considering all known devices, the motive power for the condensate to rerun to the evaporator has been derived mainly by one of two natural forces: (1) Gravity, used in device known as a Thermosiphon and (2) Force of capillary action, used in a device known as a heat pipe. When properly installed, either of these devices has proven to work effectively; however each has specific disadvantages of its own.

In the thermosiphon construction, the boiling liquid carrying from a heat collector goes up to the heat spreader through the upward tube and after heat dissipation the condensed liquid comes back with gravity pull through downward tube. The thermosiphon has a major limitation as its operation and performance is dependent on gravity and relative position of its components. It must be configured so that the condenser is located relatively above the evaporator with respect to the gravity. In a system so configured, the condensate will be pulled downhill from the condenser to the evaporator due to gravity. Consequently, if the evaporator is located above the condenser the working fluid liquid will not come back to the evaporator, thus the machine will not work. This is why a thermosiphon cannot work for a system where the thermal energy is required to be transferred against the gravitational force. Furthermore, if the location of heat source is above the heat-sink relative to gravity, the thermosiphon will not work. This also implies that a thermosiphon system will not work where the gravity is low or does not exist. In addition to the relative position of evaporator and condenser, the second major limitation of a thermosiphon is the relative position of the duct carrying vapor or liquid. At the evaporator, the relative position of the duct carrying vapor must be gravitationally above the duct carrying liquid back from the condenser.

The heat pipe type of system consists of a sealed aluminum or copper container whose inner surfaces are formed of or coated with a capillary wicking material. It can transport heat at zero gravity, micro-gravity or against gravity by an evaporation-condensation cycle with the help of porous capillaries that form the wick. The wick provides the capillary driving force to return the condensate to the evaporator. The major constrain of heat pipe is the relative weakness of capillary force which can pull condensate through capillary passageway only very slowly, limiting the rate of thermal energy transfer. In addition to that, another problem that can cause the thermal energy to shut down is, when there is thermal overload. A thermal overload causes vapor plug in the capillary structure and thermal energy transfer stalls until vapor can dissipate. Drying of the wick also limits the thermal energy transfer. This drying of the wick occurs when the rate of evaporation is higher than the capillaries can return the liquid. In addition to the capillary force, another issue is that the heat transfer rate of a heat pipe is dependent on the length and diameter ratio of the pipe. Efficiency of a heat pipe significantly goes down as the diameter of the tube becomes smaller and the length becomes longer. Also, typically the heat pipe systems are constructed of rigid metal tubes and it is very hard to make the pipes fit in many spatially restrictive applications.

Both thermosiphon and heat pipe systems have some advantages as well. In a properly installed system both devices are self starting and self regulating. Accordingly, in these devices, operation starts automatically when the temperature of the heat source rises above the temperature of the boiling pint of the working fluid. The devices are self-regulating, meaning that, within the limits of their transport capacity, the device performance will automatically tend to match the thermal load. In addition, such devices do not require any external source of energy for normal operation or control, do not any have moving parts, and are very quiet while in operation.

Other heat dissipation and delivery systems have been used as well, but all have limitations and disadvantages in certain applications, particularly in the semiconductor field.

Considering all the current circumstances, there is a very strong demand for a device or mechanism that: can transfer thermal energy at high rate and high efficiency; that can work independent of gravity and orientation; and that retains all the advantages of the prior art, such as self-starting, self-regulating features, quiet in operation and being independent of external sources of energy for operation or control,

Consequently, a need remains for improved methods, systems and mechanisms for transferring heat away from and to components in an efficient manner.

### DISCLOSURE OF INVENTION

Accordingly, it is an object of the present invention to provide a self-actuating and regulating heat exchange system which works independently of gravity.

It is another object of the invention to provide a system which works independently of orientation.

It is a further object of the system to provide a method for transferring thermal energy which uses pressure differential created during evaporation and after condensation as the driving force for vapor-liquid movement.

It is yet another object of the present invention to provide a thermal energy transfer system which is self-starting, self-regulating and requires no external energy for its normal operation or control.

It is a further object of the invention to provide a system which can act to either cool or heat a desired component, although the heating operation will not ordinarily be self-starting.

Briefly, the preferred embodiment of the present invention is a self-actuating and self-regulating heat exchange system adapted for use with electronic components, particularly semiconductor chips or for any other heat source component. The system is a closed loop fluid flow circuit having operational elements interconnected by fluid flow tubes. A heat sink element is mounted against the electronic component or any other heat source to conductively receive heat therefrom. A phase-changing fluid passes through a chamber in the heat sink block and is heated to vaporization point in operation. Vaporized fluid passed through the tube array to a cooler/condenser where it exchanges heat with the ambient atmosphere and is condensed back into liquid phase. A bladder subsystem is situated in the return path from the condenser to the heat sink. The bladder subsystem includes a one-way inlet valve and a one way exit valve on opposite ends of an expandable bladder. The expandable bladder may have elastic properties and acts as the flow regulation element of the system. The system operates in continuous cycles and is activated by heat generated in the component and conducted to the chamber.

An advantage of the present invention it that it is very efficient and convenient for transporting heat over greater distances than has been feasible with in prior devices.

Another advantage of the inventive system is that it provides much greater flexibility in the relative placement of heat sink and condenser elements.

Yet another advantage of the inventive system is that it has higher rate of heat transfer due to the combination of liquid vapor phase-change heat transfer methodology and stronger condensate return force.

Still another advantage is that the inventive system can keep the heat source temperature within a limited of range about a given point for which optimal operation of the component.

A further advantage of the system is that operate almost without any noise or vibration.

Another advantage of the present invention is that varying parameters such as the size and expandability of the bladder, the triggering pressure of the one-way valves, the vaporization point of the selected phase-change fluid and the initial pressure of the circuit can be used to vary the operational vaporization temperature to conform to the best operation of the electronic component or any other heat source.

Still another advantage of the system is that the lack of complex moving parts reduces wear and tear, such that the system is expected to be durable, reliable and very long lasting.

Yet another advantage is that, due to simplicity in design and components, the system provides relatively lower manufacturing cost.

These and other objects and advantages of the present invention will become clear to those skilled in the art in view of the description of the best presently known modes of carrying out the invention and the industrial applicability of the preferred embodiments as described herein and as illustrated in the several figures of the drawings.

### BRIEF DESCRIPTION OF THE DRAWINGS

The purposes and advantages of the present invention will be apparent from the following detailed description in conjunction with the appended drawings in which:

FIG. 1A is stylized, simplified, two dimensional cross sectional views of a heat exchange system, and FIG. 1B is stylized three dimensional view of the heat exchange system according to a preferred embodiment of the present invention, shown in use with an electronic chip;

FIG. 2A and FIG. 2B are cross sectional views of the heat sink portion of the system;

FIGS. 3A to 3B are stylized cross sectional views of the bladder subsystem of the invention, showing the expandable bladder in constricted and expanded modes respectively, designed for a system that has equal or higher internal pressure compared to ambient pressure;

FIGS. 3C to 3D are stylized cross sectional views of the bladder subsystem of the invention, showing the expandable bladder in expanded and constricted modes respectively, designed for a system that has lower internal pressure compared to ambient pressure;

FIG. 4 is a flow chart depicting various stages in the typical operation of the present invention;

FIGS. 5A through 5E are stylized cross sectional views, similar to those of FIG. 1, showing the inventive system in the various stages of operation referred to in FIG. 4;

FIG. 6 illustrates surface temperature and internal pressure of heat sink of the heat exchange system over time.

### BEST MODE FOR CARRYING OUT THE INVENTION

A preferred embodiment of the present invention is a heat exchange system and method suitable for use in a variety of applications where maintenance of temperature in an operational component is desirable. A particularly preferred embodiment, adapted for use with semiconductor chips is shown in the several figures of the drawing and is designated by the general reference character 10. One of the intentions of the present invention is to use in electronic and circuit board applications. The applicability of the present invention either for cooling an electronic chip, or cooling any other hot devices are very similar, even though for simplicity to describing, electronic chip is repeatedly mentioned.

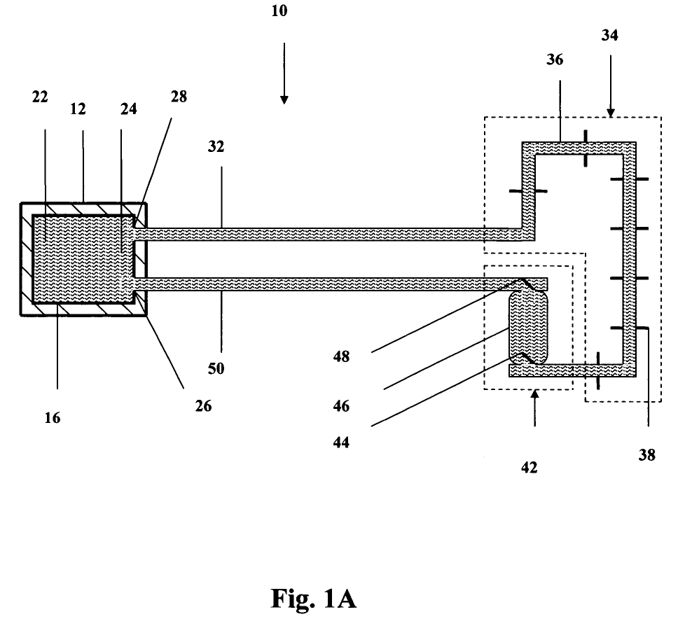

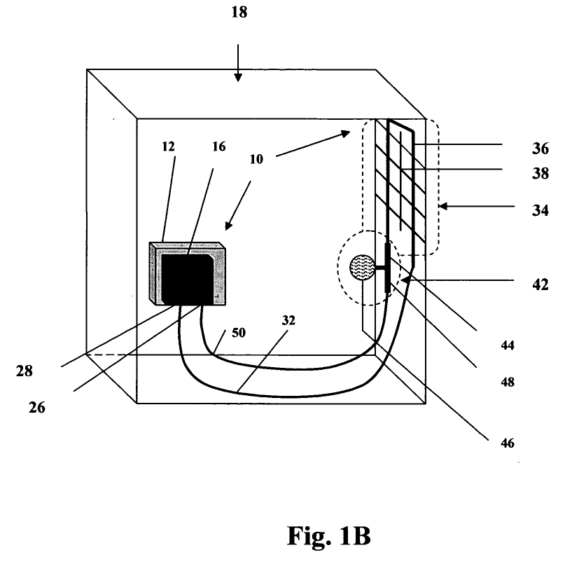

Referring now to FIG. 1A and FIG. 1B are tow different views of the preferred embodiment of the heat exchange system 10 is shown in a stylized illustration. Refer to FIG. 1B, the system 10 is adapted for use with an electronic component-box 18 and is illustrated as mounted on a stylized semiconductor chip 12. Since the shapes and dimensions of the chips 12 are widely variable and not germane to the operation of the system 10, the components are shown in stylized form only. It is understood that the relative shapes and sizes will conform to the needs of a particular situation and the operation is not dependent on these aspects. FIG. 1A. is a simplified two dimensional and cross sectional view of the heat exchange system 10 showing all internal parts to help better understanding the system 10 and it's operation, and FIG. 1B. is a three dimensional view of heat exchange system 10, showing how the actual system 10 would look like while being used to cool electronic chip inside an electronic component-box 18.

The system includes a heat sink 16 which is directly mounted on the chip 12. The heat sink 16 abuts directly against the mounting surface of the chip 12. The block and particularly the contact surface between the chip and the heat sink are strongly heat conductive materials to allow conduction of thermal energy from the chip 12.

The interior of the heat sink includes a chamber 22 for containing a fluid 24 therewithin. The chamber receives thermal energy form the contact surface between the chip and the heat sink, and conducts it into the interior to affect the fluid 24. The fluid 24 is selected to have a boiling point at the given system internal pressure within the operational temperature range of the chip 12. For a typical chip which can operation at relatively high temperature (around 100° C.) the fluid may be water (H₂O), while other fluids may be selected for components with different cooling range requirements including methanol (around 64 C ), ethanol (around 78 C) and acetone (around 56 C) while working at atmospheric pressure. During operation, as discussed hereinafter, the fluid 24 will exist in both liquid and gaseous states within the chamber 22.

The heat sink 16 is provided with an inlet port 26 and an outlet port 28 which connect the chamber 22 to fluid flow tubes which facilitates the flow of the fluid 24 within the sealed heat exchange system 10. A fluid outlet tube 32 connects to the outlet port 28 and a fluid inlet tube 50 is connected to the inlet port 26.

The fluid outlet tube 32 carries the fluid 24 to a cooling unit 34, also referred to as a condenser 34. The cooling unit 34 may be of several conventional types, but is characterized in the preferred embodiment as having a continuous cooling tube 36 and a plurality of fins 38. The fins 38 are constructed of heat conductive material and it provides a relatively larger surface area, which is exposed to the ambient temperature (air, air propelled by a fan, or additional cooling fluid). The fins 38 act to cool the fluid 24 flowing therethrough and through the cooling tube 36.

From the condenser 34 the fluid 24 continues through a condenser cooling tube 36 of whatever length is necessary for the geometry of the system to a bladder subsystem 42. The bladder subsystem 42 includes an inlet valve 44, an expandable bladder 46 and an outlet valve 48. The bladder subsystem 42 acts as a continual pressure and flow regulator for the entire heat exchange system 10.

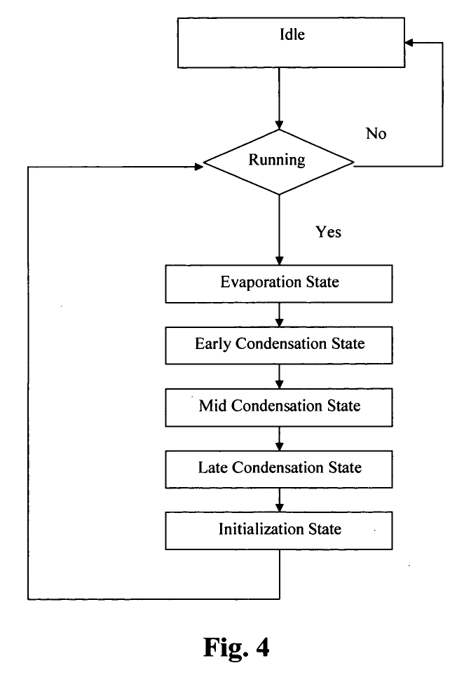

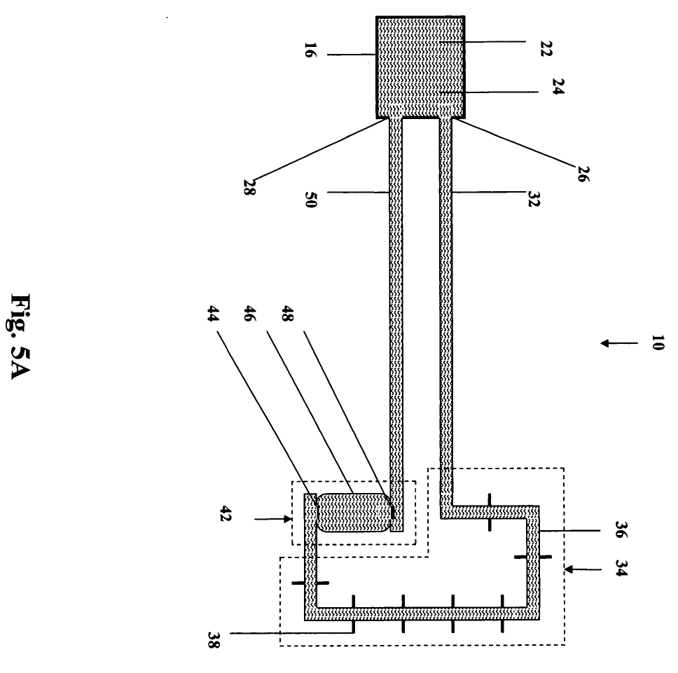

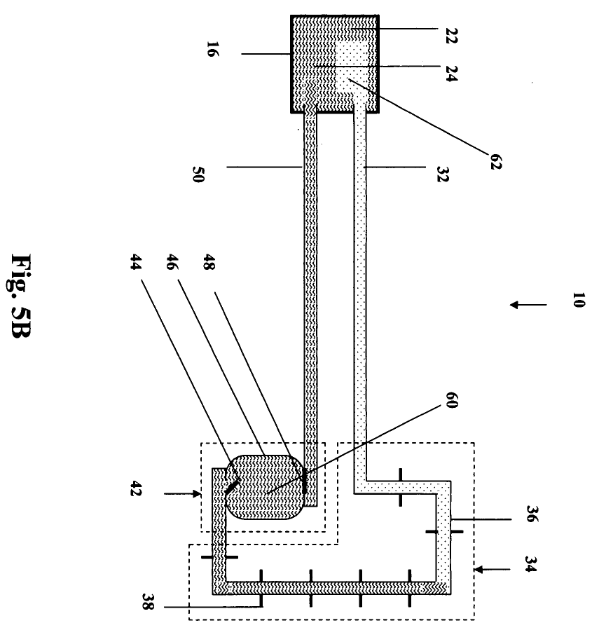

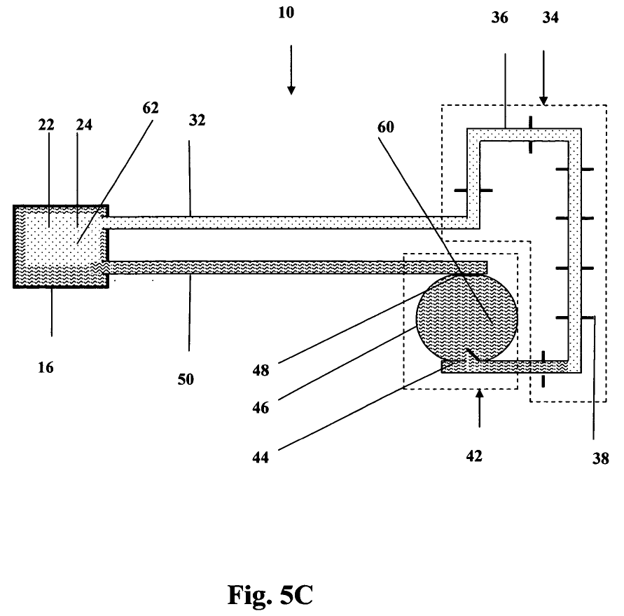

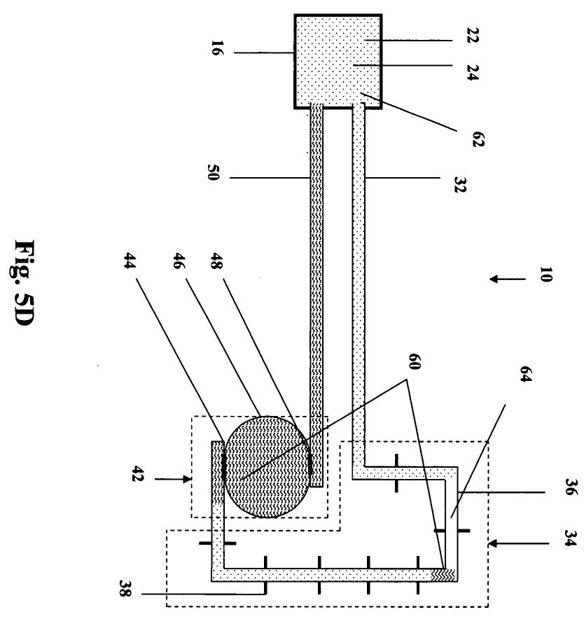

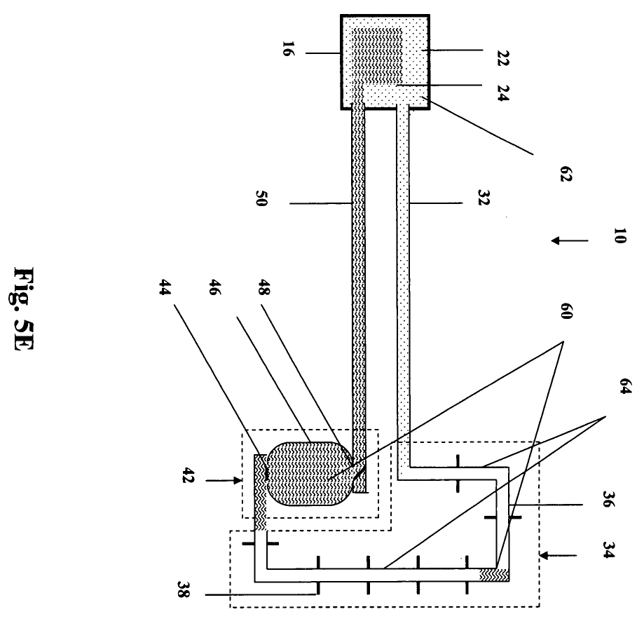

From the bladder subsystem 42 the fluid circuit is completed by a return tube 50 which connects the outlet valve 48 to the inlet port 26 of the heat sink 16. The operation of the fluid circuit of the system 10 is described in connection with FIG. 4 and the various illustrations of FIGS. 5A through 5E.

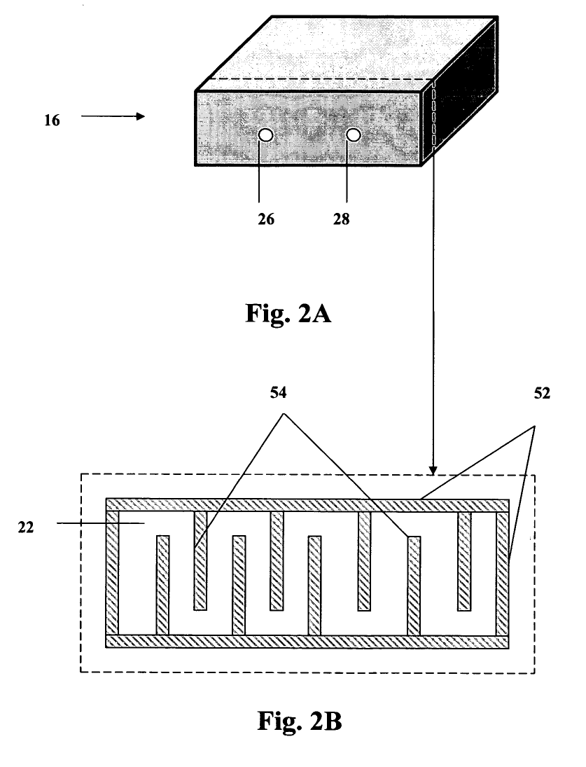

FIG. 2A. and FIG. 2B. further illustrates a preferred construction of the heat sink 16. FIG. 2A. shows a three dimensional view of the heat sink looking from outside, along with inlet port 26 and outlet port 28, and FIG. 2B shows a two dimensional cross section view of the heat sink, looking from the inlet 26 or outlet port 28 side. The heat sink 16 is shown in this illustration to be rectangular in shape to fit with the contact surface flush against a heat generating item such as the chip 12, though it is not limited to any particular shape. The heat sink 16 is shown to be constructed with a plurality of chamber walls 52 formed of highly heat conductive materials so as carry the heat evenly about the internal chamber 22 containing the phase changing fluid 24. The interior of the chamber 22 is further provided with a series of baffles 54 which extend from the chamber walls 52 and the contact surface between the chip and the heat sink so as to provide maximal surface area contact with the fluid 24. The baffles are shown to alternate to facilitate heat transfer and to cause even flow of fluid 24 within the chamber 22. The baffles 54 have a function analogous to that of the fins 38 except that the baffles 54 conduct the heat to the fluid 24 from the contact surface between the chip and the heat sink, whereas the fins 38 conduct heat out of the fluid 24 and into the ambient conditions.

The illustration further shows the inlet port 26 and the outlet port 28 as being situated on the far wall 52. It is understood that the positioning of the ports is a matter of particular design choice for the particular construction and is not fixed, provided that free flow of fluid 24 is facilitated into and out of the chamber 22.

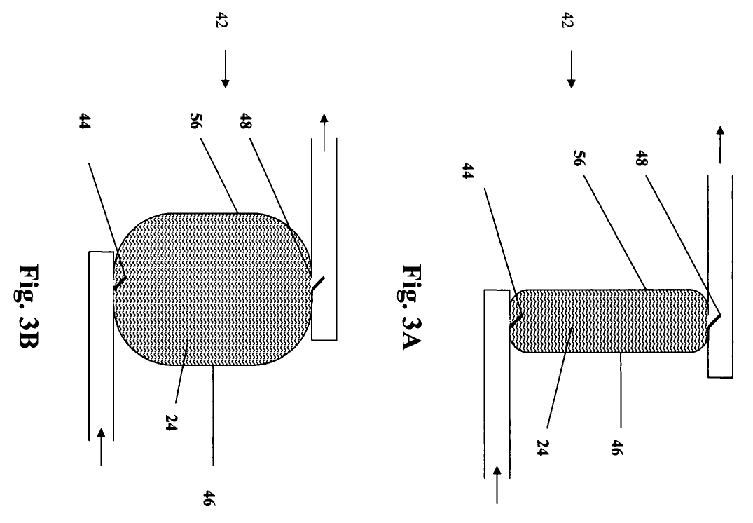

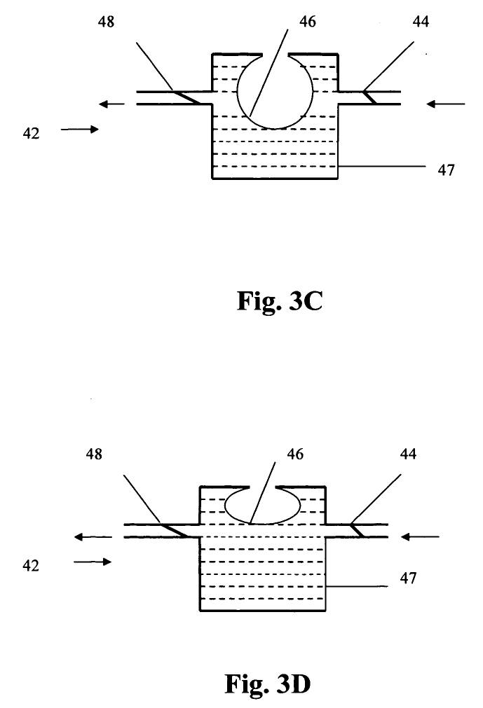

The structure and operation of the bladder subsystem 42 is illustrated in the fanciful cross sectional drawings of FIG. 3. FIG. 3A shows the expandable bladder 46 in a constricted mode contained fully with liquid fluid 60, while FIG. 3B shows the expandable bladder 46 in distended or expanded mode, also with contained liquid fluid 60.

If the heat exchange system 10 is designed to work in normal ambient air pressure with normal boiling point of the phase change liquid 24, the expandable bladder 46 requires no elastic property. Expandable bladder 46 will expand during evaporation providing no significant resistance against the incoming liquid 60, and will provide room for incoming liquid 60. Expandable bladder 46 will contract after condensation, when extra liquid 60 leaves the expandable bladder 46. Pressure difference created after condensation between ambient pressure at the expandable bladder 46 and the low pressure zone at chamber 22, outlet tube 32 and the condenser 34, acts as the driving force for liquid movement in this case.

If the heat exchange system 10 is designed to work in low or zero ambient air pressure, the expandable bladder 46 needs to be elastic to absorb energy while expanding during evaporation by providing resistance against incoming liquid 60, and use this stored energy as driving force to push the liquid out from expandable bladder 46 to low pressure zone (chamber 22, forward tube 32 and the condenser 34), created after condensation.

FIG. 3C. and FIG. 3D. shows the bladder sub system 42 in an alternate embodiment mode, when the heat exchange system 10 is designed to keep relatively lower pressure inside the system 10 compared to it's ambient. This condition is required to achieve lower boiling point of the phase-change fluid 24 inside the system 10. For example, to achieve boiling point of 70 C, while water is the phase-change fluid 24 in the system 10 and 1 bar is the ambient air pressure. Since pressure inside the heat exchange system 10 is relatively lower than ambient pressure, during idle state, the expandable bladder 46 will be pushed more inward (FIG. 3C) inside the bladder holding box 47 by ambient pressure. During evaporation, the bladder will contract (FIG. 3D, be less inward inside the bladder holding box 47) to give room for the incoming liquid 60, but will still hold lower pressure within the system 10 at all the time. After condensation the expandable bladder 46 will go back to its original shape (FIG. 3C, be more in word again inside the bladder holing box 47).

A pair of one-way check valves, the inlet valve 44 and the outlet valve 48, facilitates the operation of the bladder subsystem 42. The inlet valve 44 receives nominally cooled fluid 24 from the cooling unit 34 and delivers the fluid to the interior of the expandable bladder 46. The outlet valve 48 is similar in structure and is oriented in the same direction as the inlet valve 44 and receives normally cooled liquid from the expandable bladder 46 and delivers the fluid to the interior of the heat sink chamber 22. The combination of the one-way check valves (inlet valve 44 and outlet valve 48) insures the unidirectional flow of fluid 24 within the system 10.

Referring now to FIG. 4, the operation of the heat exchange system is illustrated in a flow chart. The chart should be considered in association with the several figures of FIG. 5. Each of FIGS. 5A through 5E illustrates the condition of the system 10 at various stages of operation. The principal driving conditions of the system 10 depend on the phase of the fluid 24, whether it be the cooler liquid phase 60 (illustrated as ˜ in the drawings) or the higher temperature gaseous phase 62 (illustrated as ° or ^{•} in the drawing). The vacuum 64 illustrated as empty space in the drawing, creates after condensation of gaseous phase liquids 62.

FIG. 5A illustrates the system 10 in the idle state, where no significant heat is being generated in the chip 12 or the other heating component. In this state, the temperature of the fluid within the system 10 is below the boiling or vaporization point of the fluid (100° C. for water). All of fluid 24 is liquid phase 60, the bladder 46 is in constricted mode, and no flow occurs through the entire circuit. It is noted that the system 10 is pressure sealed with, preferably, no gas component in the flow tubes. That is, when the system 10 is idle, as shown in FIG. 5A, nothing but liquid phase fluid 60 exists in the interior of the system 10. When the heat source component or the chip is active and generating heat, the system 10 goes into running mode, as illustrated in FIGS. 5B through 5E.

The system is shown in an early evaporation state in FIG. 5B. In this illustration it may be seen that the heat generated in the chip 12 or the other heating component has caused at least some of the fluid 24 in the chamber 22 to vaporize into the gaseous phase 62. Since condensation at the condenser 34 is proportional to the volume of condenser tube 36 filled with gas, and since at this early condensation state most of the condenser tube 36 is filled with liquid phase fluid 60, at this early condensation state the rate of condensation is much lower that the rate of evaporation. This extra energy for evaporation creates expansion pressure and results in some of the gaseous phase fluid 62 to flow into the outlet tube 32. This pressure begins to force the liquid phase fluid 60 in the cooling unit 34 to condenser cooling tube 36 into the bladder subsystem 42. The pressure forces the inlet valve 44 partially open so additional fluid 24 (cooled, so liquid phase fluid 60) enters the expandable bladder 46 while the outlet valve 48 remains closed due to opposite pressure direction at this time. If the heat exchange system 10 is designed with no elastic property in the expandable bladder 46, then the expandable bladder 46 will expand providing very insignificant resistance against the incoming liquid phase fluid 60. If the heat exchange system 10 is designed with added elastic property in the expandable bladder 46, then the expandable bladder 46 will expand providing added resistance against the incoming liquid phase fluid 60. If the heat exchange system 10 is designed with added elastic property in the expandable bladder 46 similar to FIG. 3C and FIG. 3D, then the expandable bladder 46 will contract providing helping force for the incoming liquid phase fluid 60. During the early condensation state, the liquid push out continues until enough volume of the cooling tube 36 is filled with gaseous phase fluid 62 so that the evaporation rate inside the chamber 22 of the heat sink 16 become equal to the condensation rate at the cooling tube 36 of the condenser 34.

FIG. 5C shows the system in a mid-condensation state. This occurs when enough volume of the cooling tube 36 is filled with gaseous phase fluid 62 so that the evaporation rate at the chamber 22 of the heat sink 16 become equal to the condensation rate at the cooling tube 36 of the condenser 34. This established a state of heat transfer equilibrium. This is the longest lasting state and maximum heat gets transferred in this state. The return tube 50 is still filled with liquid phase fluid 60, the one-way nature of the outlet valve 48 preventing the liquid phase fluid 60 into the return tube 50 from the chamber 22. This provides significant back pressure on the outlet valve 48 and maintains it in the closed mode. The fluid 24 in the chamber 22 is nearly completely converted to gaseous phase 62 at the end of this stage, with some liquid 60 still being present around the edges.

In the late condensation stage illustrated in FIG. 5D the liquid in the chamber 22 is essentially all vaporized breaking the thermal equilibrium established between the evaporator and the condenser during the mid condensation state. Now heat producing in the heat source keeps getting stored in the heat sink 16 raising the temperature slightly. During this phase, the cooling provided by the fins 38 in the condenser 34 catches up and some of the gaseous phase fluid 62 begins to condense in the cooling tube 36 creating vacuum 64. This results in a portion of the cooling tube 36 containing a mixed phase condensate and vacuum. The condensation of the gaseous fluid 62 back into liquid phase 60 reduces the internal pressure within the cooling tube 36 (while the expanded bladder 46 provides back pressure) so the inlet valve 44 is no longer forced open and begins to close.

In FIG. 5E the final stage of the cycle is illustrated. This is referred to as an initialization stage and is exampled by rapid condensation in the cooling unit 34 since after the evaporation is completely finished, no more heat gets transferred to the condenser 34, even though heat dissipation remains at the same rate at the condenser 34. This results a rapid vacuum condition in the condenser 34 and consequently to the outlet tube 32, chamber 22 and the inlet tube 50. This eliminates the back pressure on the return tube 50 and instead leads to vacuum pressure drawing the liquid phase fluid 60 in the return tube 50 into the chamber 22. The resulting pressure drop helps open the outlet valve 48 such that the bladder 46 may contract and use ambient pressure or elastic pressure or both pressure together to force liquid phase fluid 60 through the outlet valve 48 into the return tube 50 to the chamber 22, and then the outlet tube 32 and cooling tube 36 to fill out the vacuum. At this stage liquid phase fluid 60 re-enters fills out the complete system again and a gradual return to the idle state. Of course, if the heat is still being generated in the heat source or the chip 16, the cycle does not completely rest, but instead goes back into evaporation, early condensation, mid condensation and initialization stages and the cycle continues until the heat generation in the chip 16 subsides.

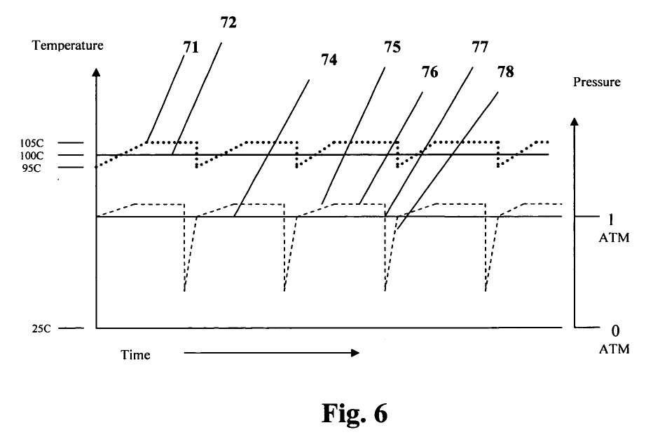

Referring now to FIG. 6, this shows the surface temperature and internal pressure diagram of heat sink 16 of a typical heat exchange system 10 over time, working in normal atmospheric ambient pressure with water as the phase-change fluid 24. The diagram in its primary axis (left had side) shows the relative temperature 71 of the heat sink 16 compared to the boiling point of water 72 over time. Note that the temperature of the heat sink 16 keeps oscillating right above and below the boiling point 72 of the phase change liquid, here the water [100 C] over time. The diagram in its secondary axis (right hand side) shows the relative pressure inside the chamber compared to its ambient atmospheric pressure. Assuming the heat exchange system 10 is working in an ambient having outside pressure equal to 1 ATM 74. While in operation, pressure inside the chamber 22 increases 75 at the evaporation state and early condensation state, pressure remains elevated and steady 76 at mid condensation state, and pressure suddenly drops 77 at late condensation state, and pressure increase again 78 up to its ambient pressure 74 at initialization state.

As an alternate use of the present invention, a heat exchange system 10 can be used to heat up a component instead of cool off. In that case, the heat dissipated from the cooling tube 36 can be used to worm up any component while using heat intake at the heat sink 16 as the source of heat.

Another alternate use of the present invention, a compound heat exchange system 10 having multiple heat sinks 16 connected to a single condenser 34 and single bladder subsystem 42. For example: an electronic equipment with multiple micro-chips 12, each micro-chip 12 having one heat sink 16 attached, and outlet port 28 of each heat sink 16 is connected to the single condenser tube 36 of a compound heat exchange system 10 with separate outlet tubes 32; and inlet port 26 of each heat sink 16 is connected to the single outlet valve 48 of the, of that compound heat exchange system 10 with separate return tubes 50.

The following parameters, dependencies, equations and design guidelines relate to the present invention:

The period of a complete cycle can be defined as the time between two successive Initialization Stages and is referred to as “T”.
T:=(V×L)/R [:=is directly proportional to]
Where: V=Chamber volume 22, L=Latent heat of the selected phase change fluid, and R=Rate of heat dissipation at the condenser 34

The heat dissipation capacity of the cooling Unit/Condenser 34: is selected to be greater or equal to the typical heat production capacity of heat source (considering all dependencies: ambient temperature, air circulation and etc).

Any additional heat dissipation capacity of the condenser 34 will increase the period T by extra time, Delta t, where Delta t=(Conductive heat coefficient of the fluid*Volume of the chamber*Temperature difference of fluid below its vaporization point at the condenser)

The fluid 24 may be selected to have a vaporization point significantly higher than the expected ambient temperature surrounding the cooler unit 34 in order to maximize cooling efficiency.

If the fluid 24 is selected to have a high latent heat the net result is likely to be a slow and steady cycle period T.

The volume for the expandable bladder 46 while expanded (FIG. 3B) is at least equal to the combined volume of: (internal volume of outlet tube 32+the internal volume of the cooling tube 36+chamber volume 22).

For the ideal case, the one-way valves should be open at (0+) pressure and closed at (0−) pressure. On the other hand, if pressure to open the inlet valve 44 is (0+Delta P), this Delta P will act increasing the system internal pressure and accordingly the boiling point of the phase change liquid, and if the pressure to open the outlet valve 48 is (0+Delta Q), this Delta Q will act reducing the return force created by two pressure zones during Initialization state.

During evaporation states, the expandable bladder 46 remains at: (ambient air pressure+added bladder elastic pressure). During initialization state, a low pressure zone exists inside the chamber 22 of the system. This pressure difference between the two pressure zones can be called the return force that pushes the liquid phase fluid 60 back from the bladder subsystem 42 to the heat sink 16. If it is assumed that the ambient atmospheric pressure of the system 10 is =Pₐ and the added elastic pressure of the expandable bladder 46 is =P_{b} then the total pressure difference between the high and low pressure zones during initialization stage is =(Pₐ+P_{b}), considering 0 pressure at low pressure zone. And if the outlet valve opening trigger pressure is Prv, the added resistance to liquid motion created by liquid viscosity along the return path is Rvs and the potential difference due to relative level of the heat sink 16 and the condenser 34 is E, and then the net return force=(Pa+Pb)−(Prv+Rvs+E).

For a typical system adapted to operate with a CPU chip generating up to 200 W of heat energy in a computer, the heat sink 16 will be constructed of solid metal of copper or aluminum with (5×5×1) cm chamber volume and having a contact surface between the heat sink 16 and the chip 12 with dimensions of about 5×5 cm. The outlet tube 32 and return tube 50 flow tubes will be formed of plastic materials and have an interior diameter of 2.5 mm to provide optimal flow of the fluid 24, having about 50 cm of length for each tubes to provide easy placement of the condenser 34. The cooling tube 36 of the condenser unit 34 will be made of copper or aluminum tubes with internal diameter of 5 mm and about 100 cm in length having fins attached. The bladder subsystem 42 will include inlet valve 44 and outlet valve 48 with low trigger open pressure and almost no reverse flow. The bladder subsystem 42 will include expandable bladder 46 having dimensions to hold up to 50 cc of water while expanded without utilizing any elasticity during expansion. For this typical installation the selected phase change fluid 24 will be water (preferably de-ionized or distilled).

A heat exchange system designed to cool engines for automotives will be bigger in proportion to satisfy need for higher heat transfer requirements, and the same thing applies for other systems. As indicated above, the materials and dimensions of the various elements may be custom selected to meet the needs of particular applications.

While various embodiments have been described above, it should be understood that they have been presented by way of example only, and not as limitation.

### INDUSTRIAL APPLICABILITY

One of the usages of the present invention is adapted in electronic component systems such as computers, circuit boards and the like.

A typical installation of the heat exchange system 10 will have the heat sink 16 mounted directly on an electronic chip such as a CPU which generates substantial heat during usage. The excess heat generated by the chip 12 will be conductively transferred to the heat sink 16 through the contact surface which abuts against the mounting surface of the chip 12. If the chip 12 is expected to be operable at a temperature of somewhat around the vaporization point of water [100° C. (212° F.)] the selected fluid 24 will be water. For lower temperature requirements, other liquids are used including methanol [64° C.], ethanol [78° C.] and acetone [56° C.]. The heat exchange system 10 will transfer heat from the heat sink 16 to the condenser 34 located any where on the electronic box or device.

Another use of the present invention is to prevent over heating of electrical transformers, motors, switches, and other electrical equipments. Since heat production rate of electrical equipment is expected to be higher compared to the heat production rate of electronic chip, all the parameters and components of the heat exchange system 10 is expected to be higher and bigger respectively.

Another use of the present invention is for cooling internal combustion engine used in automobiles or other devices. Currently most internal combustion engine uses forced liquid cooling system. Forced liquid cooling system uses pump for operation and electronic systems for controls. Both pump and electronic control system requires power and suffers normal wear and tear over time. It can be beneficial to replace existing complex and power consuming forced liquid cooling system with a self regulating, efficient, simple, no power consuming heat exchange system described in the current invention.

Another use of the present invention is to transfer heat from space crafts and satellite equipments. Since satellite systems look for low power consuming, low maintenance required and long lasting devices for all its operation, the present invention can be a good choice for heat transfer modules.

Another use of the present invention is to prevent over heating components due to heat production by chemical or nuclear reactions. The heat exchange system will be much bigger for this application and can provide similar benefit that described earlier for internal combustion engine.

Another use of the present invention is to prevent over heating any mechanical/industrial equipment under frictions such as car brakes.

Another use of the present invention is to produce hot water for household usage in cold area from sun light. For this application, heat sink 16 of the heat exchange system 10 will collect heat from sunlight and cooling tube 36 of the condenser 34 will deliver that heat to a water reservoir.

Another of the use of the present invention is to lower temperature of pipes carrying hot fluids such as Trans Alaska oil pipe. In which the heat sink 16 will collect heat from the hot pipe and deliver it to some relatively cold places.

Another use of the present invention is to prevent homes from over heating in hot geographic areas. The boiling point of phase-liquid 24 for this application will be selected much lower than water (preferably below 30 C). Heat sink 16 of the heat exchange system 10 will be set in convenient places of the home and the condenser 34 unit will be placed some cooler places, such as under a swimming pool.

For the above, and other, reasons, it is expected that the heat exchange systems of the present invention will have widespread industrial applicability. Therefore, it is expected that the commercial utility of the present invention will be extensive and long lasting.

I claim:

1. A heat exchange system, comprising:
A heat sink member positions to receive thermal energy from a heat generation component, said heat sink member including a chamber therewithin, an inlet port and an outlet port;
a condenser unit for cooling fluids passing therethrough;
a bladder subsystem including and expandable bladder a one-way inlet valve and a one-way outlet valve
an array of fluid flow tubes extending from said outlet port to said condenser unit, from said condenser unit to said inlet valve of said bladder subsystem and from said outlet valve of said bladder subsystem to said inlet port, so as to form therewith a sealed circuit; and
a phase change fluid filling said sealed circuit, said phase change fluid at the internal pressure of the said sealed circuit having a vaporization point selected to be within the operating temperature range of the heat generation component.

2. The heat exchange system of claim 1, wherein
said heat sink includes a contact surface for abutting against the heat generating component and conductively receiving exchanging thermal energy therewith.

3. The heat exchange system of claim 1, wherein
said heat sink is composed of non-collapsing, heat-conductive materials, including but not limited to copper or aluminum; and
said chamber of said heat sink is provided with internal baffles.

4. The heat exchange system of claim 1, wherein
said condenser is composed of non-collapsing, heat conductive tubes or containers, made of copper, aluminum or similar materials; and
said tubes or containers of said condenser is be provided with fins.

5. The heat exchange system of claim 1, wherein
said expandable bladder has sidewalls selected to provide zero, positive or negative elastic pressure into said sealed circuit relative to pressure of said expandable bladder.

6. The heat exchange system of claim 1, wherein
said array of fluid flow tubes are non collapsing flexible tubes, made of materials including but not limited to plastic, rubber; or
said array of fluid flow tubes are non collapsing inflexible tubes, made of materials including but not limited to metals.

7. The heat exchange system of claim 1, wherein
the rest state of the system, when the temperature of the heat generation component is below the vaporization point of said phase-change fluid at its current pressure, has all of said phase-change fluid within the system in liquid phase; and the working states of the system, when the temperature of the heat generation component is above the vaporization point of said phase-change fluid at its current pressure, has all of said phase-change fluid within the system in both liquid and vapor phase.

8. A method for transferring heat between a component having a higher temperature and a temperature zone having a lower temperature, in steps comprising:
providing a sealed circuit containing a phase-change fluid therewithin, said phase-change fluid having a vaporization temperature within said desired operating range at the internal pressure of the said sealed circuit, said circuit having flow restrictive means permitting said phase-change fluid to flow only in one direction therein;
providing a heat sink within said sealed circuit, situated to conductively exchange thermal energy with said component, said heat sink including a chamber through which said phase-change fluid may flow;
providing a condenser element downstream in said circuit from said heat sink, said condenser being associated with the temperature zone so as to cool fluid passing therethrough and return gaseous phase fluid to liquid phase fluid during said passage; and
providing a bladder subsystem downstream from said condenser unit and upstream form said heat sink, said bladder system including an expandable bladder for regulating fluid flow within said circuit.

9. The method for transferring heat of claim 8, wherein
said flow restrictive means include a one-way inlet valve upstream of said expandable bladder and a one-way outlet valve downstream of said expandable bladder.

10. The method for transferring heat of claim 8, wherein
the said expandable bladder expands to contain additional volumes of said phase-change fluid coming out from said heat sink and said condenser through said one-way inlet valve during evaporation, and the said expandable bladder contracts to release volumes of said phase-change fluid to the said heat sink and said condenser through one-way outlet valve after condensation.

11. The method for transferring heat of claim 8, wherein
the said selected component is a semiconductor chip, or any other heat generating device, the said temperature zone is ambient atmosphere or other temperature zone, and said phase-change fluid is methanol, ethanol, acetone, water or other phase-change fluid.

12. The method for transferring heat of claim 8, wherein
plurality of said components can be part of a single said sealed circuit.

13. The method for transferring heat of claim 8, wherein
the rate of heat transfer gets automatically controlled and adjusted depending on the heat receiving rate of said heat sink, and heat removing rate of said condenser.

14. A method of circulating phase-change fluid inside a heat exchange system wherein said heat exchange system comprises: an evaporator within a hot zone, a condenser within a cold zone, a inlet fluid flow tube, a one way inlet valve, an expandable bladder, a one-way outlet valve and a outlet fluid flow tube at an intermediated location, with members joined at their peripheries forming a hermetically-sealed circuit contained a phase-change fluid;
wherein said inlet fluid flow tube connection said evaporator and said condenser, one way inlet valve connection said condenser and said expandable bladder, one way outlet valve connecting said expandable bladder and said outlet fluid flow tube, said outlet fluid flow tube connecting said one way outlet valve and said evaporator;
and said method comprises the following steps:
vaporize said phase-change fluid within said evaporator by continuously absorbing thermal energy from said hot zone and create a high pressure zone inside the said evaporator compared to pressure at said expandable bladder;
use pressure difference to provide motive force for said phase-change fluid migration from said evaporator through said inlet fluid flow tube into said condenser;
also use said pressure difference to provide motive force to open said one way inlet valve and close said one-way outlet valve, and allow said phase-change fluid migration from said condenser into said expandable bladder through said one way inlet valve;
continue said phase-change fluid migration until said condenser is filled with enough vapor so that, thermal energy absorption at said evaporator becomes equal to thermal energy dissipation at said condenser;
continue condensing said vapor within said condenser by continuously dissipating thermal energy to said colds zone;
discontinue vaporization when said phase-change fluid inside said evaporator is completely evaporated, but continue condensing said vapor within said condenser by continuously dissipating thermal energy to said colds zone;
create vacuum inside said condenser after all vapor residing inside said condenser is condensed;
create a low pressure zone inside said evaporator, said inlet fluid flow tube and said condenser compared to said expandable bladder, by propagating said vacuum already created inside said condenser;
use pressure difference between said expandable bladder and said low pressure zone to provide motive force to open one way outlet valve and close one way inlet valve;
also, use said pressure difference to provide motive force for said phase-change fluid migration from said expandable bladder into said low pressure zone through said outlet fluid flow tube and one way outlet valve;
and repeat all above steps in sequential cycles till both said hot zone and cold zone exists.

15. The method of claim 14,
wherein while in operation, the surface temperature of said evaporator oscillates periodically above and below the boiling point of said phase-change fluid inside the system over time; and,
the pressure inside the said evaporator chamber oscillates periodically above and below the pressure at the said expandable bladder over time.

16. The method of claim 14,
wherein for said heat exchange system (considering its current design and dimensions) while in operation, the frequency of said cycles, gets automatically controlled and adjusted depending the heat production rate at the said evaporator, and heat dissipation rate at the said condenser.
